(19) United States
(12) Patent Application Publication
(10) Pub. No.: US 2025/0046724 A1
(43) Pub. Date: Feb. 6, 2025

(54) SUBSTRATE PACKAGE

(71) Applicant: Samsung Electronics Co., Ltd., Suwon-si (KR)

(72) Inventor: Eunsu LEE, Suwon-si (KR)

(73) Assignee: Samsung Electronics Co., Ltd., Suwon-si (KR)

(21) Appl. No.: 18/675,274

(22) Filed: May 28, 2024

(30) Foreign Application Priority Data
Aug. 4, 2023 (KR) 10-2023-0102078

(51) Int. Cl. H01L 23/538; H01L 23/00; H01L 23/31; H01L 23/498; H01L 25/16; H10B 80/00

(52) U.S. Cl. CPC H01L 23/5386; H01L 23/3157; H01L 23/49816; H01L 23/5385; H01L 24/16; H01L 25/16; H10B 80/00; H01L 2224/16227

(57) ABSTRACT

Provided is a semiconductor package, the semiconductor package including: a package substrate including an upper surface having a first region and a second region, the second region disposed on a level lower than that of the first region, and a plurality of wiring layers; a first semiconductor chip disposed on the first region of the upper surface of the package substrate and electrically connected to the plurality of wiring layers of the package substrate; a second semiconductor chip disposed on the second region of the upper surface of the package substrate; and an interposer substrate disposed between the second region of the upper surface of the package substrate and the second semiconductor chip and electrically connecting the plurality of wiring layers of the package substrate and the second semiconductor chip.

### CROSS-REFERENCE TO RELATED APPLICATION(S)

This application claims benefit of priority to Korean Patent Application No. 10-2023-0102078, filed on Aug. 4, 2023 in the Korean Intellectual Property Office, the inventive concepts of which are incorporated herein by reference in its entirety.

### BACKGROUND

The present inventive concepts relate to a semiconductor package.

As the performance of electronic devices increases, the development of high-performance semiconductor packages is also required in a field of a semiconductor package. Accordingly, development is being conducted to implement fine pitch and to maximize I/O in semiconductor packages in which heterogeneous chips, for example, logic chips and memory chips, are mounted together.

### SUMMARY

An aspect of the present inventive concepts is to provide a semiconductor package having improved performance.

According to an aspect of the present inventive concepts, provided is a semiconductor package, the semiconductor package including: a package substrate including a plurality of wiring layers and having a first region and a second region, such that an upper surface of the second region is disposed at a level lower than that of an upper surface of the first region; a first semiconductor chip on the upper surface of the first region and electrically connected to the plurality of wiring layers of the package substrate; a second semiconductor chip on the upper surface of the second region; and an interposer substrate between the upper surface of the second region and the second semiconductor chip, and the interposer substrate electrically connecting the plurality of wiring layers of the package substrate and the second semiconductor chip.

According to an aspect of the present inventive concepts, provided is a semiconductor package, the semiconductor package including: a package substrate divided into a first region and a second region in a horizontal direction, and including a first wiring structure in the first region and a second wiring structure in the second region, the second wiring structure connected to the first wiring structure at a boundary between the first region and the second region; a first semiconductor chip on the first region of the package substrate and electrically connected to the first wiring structure; an interposer substrate on the second region of the package substrate and electrically connected to the second wiring structure; and a second semiconductor chip on the interposer substrate and electrically connected to the interposer substrate, wherein a number of layers of the second wiring structure is less than a number of layers of the first wiring structure, and an uppermost wiring layer of the first wiring structure is on a level higher than an uppermost wiring layer of the second wiring structure.

According to an aspect of the present inventive concepts, provided is a semiconductor package, the semiconductor package including: a package substrate having a first region and a second region, such that an upper surface of the second region is disposed at a level lower than that of an upper surface of the first region; a first semiconductor package on the upper surface of the first region of the package substrate; a plurality of connection bumps between the upper surface of the first region of the package substrate and the first semiconductor package, and connecting the package substrate and the first semiconductor package; an interposer substrate on the upper surface of the second region of the package substrate; a plurality of bump structures between the upper surface of the second region of the package substrate and the interposer substrate, and connecting the package substrate and the interposer substrate; a second semiconductor package on the interposer substrate; a plurality of connection terminals between the interposer substrate and the second semiconductor package, and the plurality of connection terminals connecting the interposer substrate and the second semiconductor package; and a plurality of external connection terminals disposed on a lower surface of the package substrate.

### BRIEF DESCRIPTION OF DRAWINGS

The above and other aspects, features, and advantages of the present disclosure will be more clearly understood from the following detailed description, taken in conjunction with the accompanying drawings:

FIG. 1 is a plan view of a semiconductor package according to at least one example embodiment of the present inventive concepts;

FIG. 2 is a cross-sectional view illustrating a cross-section taken along line I-I′ of FIG. 1;

FIG. 3 is a cross-sectional view illustrating a semiconductor package according to at least one example embodiment of the present inventive concepts;

FIG. 4 is a cross-sectional view illustrating a semiconductor package according to at least one example embodiment of the present inventive concepts;

FIG. 5 is a cross-sectional view illustrating a semiconductor package according to at least one example embodiment of the present inventive concepts;

FIG. 6 is a cross-sectional view illustrating a semiconductor package according to at least one example embodiment of the present inventive concepts;

FIGS. 7 to 13 are cross-sectional views schematically illustrating a manufacturing process of a semiconductor package according to example embodiment of the present inventive concepts;

FIG. 14 is a cross-sectional view illustrating a semiconductor package according to at least one example embodiment of the present inventive concepts; and

FIG. 15 is a cross-sectional view illustrating a semiconductor package according to at least one example embodiment of the present inventive concepts.

### DETAILED DESCRIPTION

Hereinafter, with reference to the accompanying drawings, wherein like reference numerals refer to like elements throughout, example embodiments of the present inventive concepts will be described as follows. In this regard, the present embodiments may have different forms and should not be construed as being limited to the particular descriptions set forth herein. Unless otherwise specified, in this specification, terms such as ‘upper portion,’ ‘upper surface,’ ‘lower portion,’ ‘lower surface,’ ‘side surface,’ and/or the like, are based on the drawings, and may actually vary depending on a direction in which the components are arranged. For example, it will be understood that such spatially relative terms are intended to encompass different orientations of the device in use or in operation, in addition to the orientation depicted in the figures such that the device may be otherwise oriented (for example, rotated 90 degrees or at other orientations) and the spatially relative descriptors used herein should be interpreted accordingly.

Additionally, when the terms “about” or “substantially” are used in this specification in connection with a numerical value, it is intended that the associated numerical value includes a manufacturing tolerance (e.g., ±10%) around the stated numerical value. Further, regardless of whether numerical values are modified as “about” or “substantially,” it will be understood that these values should be construed as including a manufacturing or operational tolerance (e.g., ±10%) around the stated numerical values. When referring to “C to D”, this means C inclusive to D inclusive unless otherwise specified.

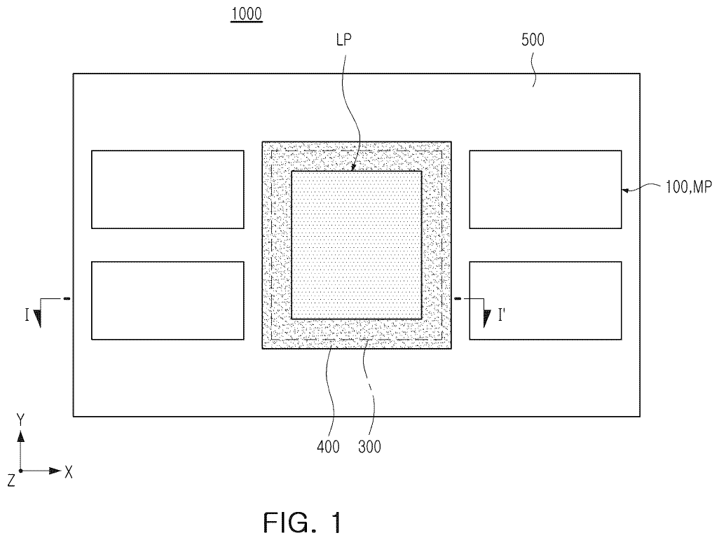

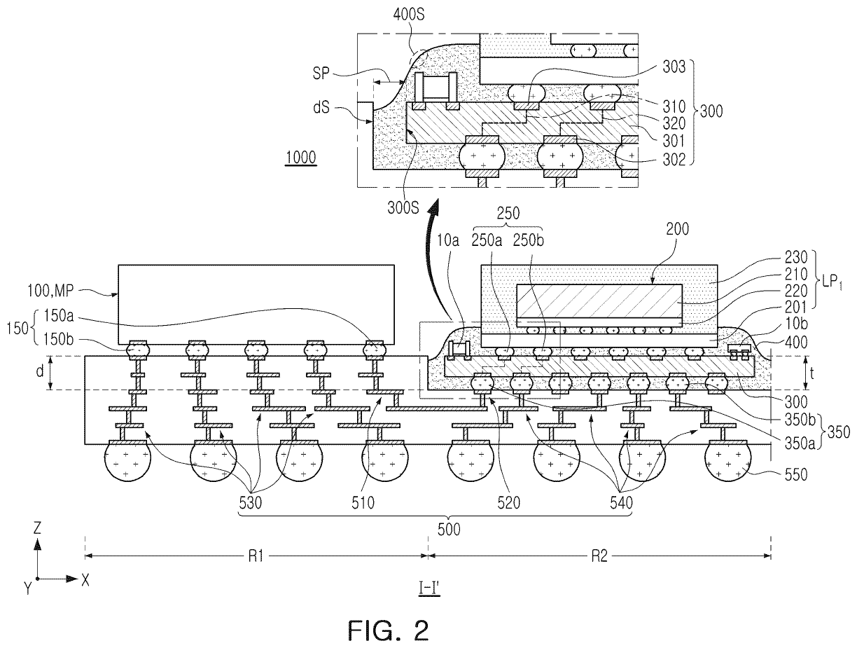

FIG. 1 is a plan view of a semiconductor package 1000 according to at least one example embodiment of the present inventive concepts. FIG. 2 is a cross-sectional view illustrating a cross-section taken along line I-I′ of FIG. 1.

Referring to FIGS. 1 and 2, the semiconductor package 1000 of at least one example embodiment may include a package substrate 500, at least one first semiconductor chip 100, a second semiconductor chip 200, and an interposer substrate 300.

The package substrate 500 is a support substrate on which the first semiconductor chip 100, the second semiconductor chip 200, and the interposer substrate 300 are mounted, and may be a substrate for a semiconductor package. For example, the package substrate 500 may be and/or include a printed circuit board (PCB), a ceramic substrate, a glass substrate, tape wiring substrate, and/or the like. A body of the package substrate 500 may contain different materials depending on the type of substrate. For example, when the package substrate 500 is a printed circuit board, the package substrate 500 may be a body copper clad laminate and/or a wiring layer may be additionally laminated on one or both sides of the copper clad laminate.

The package substrate 500 may include a structure having a step on one surface thereof. For example, the package substrate 500 may be divided into a first region R1 and a second region R2 disposed at a level lower than that of the first region R1 in a horizontal direction. An upper surface of the first region R1 may have a step d from an upper surface of the second region R2. The step d between the upper surface of the first region R1 and the upper surface of the second region R2 may range from about 50 um or less, for example, from 10 um to 40 um, or from 10 um to 35 um. The package substrate 500 may include a structure having a groove in an upper portion. An upper surface of a region in which a groove is formed may have a step from an upper surface of a region in which a groove is not formed. The step may range from about 50 micrometers (um) or less, for example, from 10 um to 40 um, and/or from 10 um to 35 um.

The package substrate 500 may include a front pad, a rear pad, and a plurality of wiring layers 510, 520, 530, and 540. The front pad may be disposed in an upper portion of the package substrate 500 so that the upper surface of the front pad is exposed. A front pad disposed in the first region R1 may be disposed on a level higher than that of a front pad disposed in the second region R2. In at least some example embodiments, the front pad may include at least one of aluminum (Al), copper (Cu), nickel (Ni), tungsten (W), platinum (Pt), gold (Au), and/or the like. The rear pad may be placed in a lower portion of the package substrate 500 so that the lower surface of the rear pad is exposed. The rear pads may be at the same level across the first region R1 and the second region R2. The rear pad may include a material similar to the front pad. However, materials of the front pad and the rear pad are not limited to the above-described materials, and may include, for example, electrically conductive materials other than the above-described materials.

The plurality of wiring layers may include at least one first wiring layer 510 and at least one third wiring layer 530 disposed in the first region R1, and at least one second wiring layer 520 and at least one fourth wiring layer 540 disposed in the second region R2. The at least one first wiring layer 510 disposed in the first region R1 and the at least one second wiring layer 520 disposed in the second region R2 may be connected to each other. For example, a first wiring layer 510 and a second wiring layer 520 may be in contact with each other at a boundary between the first region R1 and the second region R2. The at least one first wiring layer 510 and the at least one second wiring layer 520 may also be referred to as a first wiring layer structure and a second wiring structure, respectively. The at least one third wiring layer 530 may form an electrical path connecting the front and rear pads located in the first region R1 of the package substrate 500. The at least one fourth wiring layer 540 may form an electrical path connecting the front and rear pads located in the second region R2 of the package substrate 500. The electrical path may further include vias electrically connecting the front and rear pads to the at least one third wiring layer 530 and the at least one fourth wiring layer 540, respectively. The at least one third wiring layer 530 and the at least one fourth wiring layer 540 may also be referred to as a third wiring layer structure and a fourth wiring structure, respectively. The number of layers of the at least one first wiring layer 510 and the at least one third wiring layer 530 disposed in the first region R1 may be greater than the number of layers of the at least one second wiring layer 520 and the at least one fourth wiring layer 540 disposed in the second region R2. The uppermost wiring layers of the first wiring layer 510 and the third wiring layer 530 may be disposed on a level higher than that of the uppermost wiring layers of the second wiring layer 520 and the fourth wiring layer 540 disposed in the second region R2.

The plurality of wiring layers 510, 520, 530, and 540 and the vias connecting the plurality of wiring layers 510, 520, 530, and 540 may include a metal and/or metallically conductive material, for example, at least one metal material among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), alloys including two or metals thereof, and/or the like. A plurality of external connection terminals 550 electrically connected to the rear pads and the plurality of wiring layers 510, 520, 530, and 540 may be disposed on the lower surface of the package substrate 500. The external connection terminal 520 may include conductive materials, such as tin (Sn), indium (In), bismuth (Bi), antimony (Sb), copper (Cu), silver (Ag), zinc (Zn), lead (Pb), alloys thereof, and/or the like.

In at least some embodiments, the first semiconductor chip 100 may include a memory chip. The first semiconductor chip 100 may be provided in a form of a package MP (or ‘first semiconductor package’). For example, the package may include a base chip, a plurality of chips vertically stacked on the base chip, and a sealing material covering the chip structure on the base chip. The plurality of chips may comprise memory chips and/or memory devices configured to store and/or output data based on address commands and control commands received from the base chip. For example, the plurality of semiconductor chips may include volatile memory devices such as dynamic random access memory (DRAM), static RAM (SRAM) and/or the like; and/or non-volatile memory devices such as phase-change RAM (PRAM), magnetoresistance RAM (MRAM), ferroelectric RAM (FeRAM), resistive RAM (RRAM), and/or the like. In at least one embodiment, the plurality of chips may include a first chip, at least one second chip, and a third chip sequentially stacked on a base chip. For example, the base chip may be a buffer chip including a plurality of logic devices and/or memory devices in a device layer. Accordingly, the buffer chip may be configured to transmit signals from a plurality of chips stacked thereon to an outside, and to transmit signals and power from the outside to the plurality of chips. The buffer chip may perform both a logic function and a memory function through logic devices and memory devices. However, depending on the example embodiment, the buffer chip may include only logic devices and perform only the logic function.

The first semiconductor chip 100 may be disposed on an upper surface of the first region R1 of the package substrate 500. A plurality of connection bumps 150 may be disposed between the first semiconductor chip 100 and the first region R1 of the package substrate 500.

The plurality of connection bumps 150 may electrically connect the front pads disposed in the upper portion of the first region R1 of the package substrate 500 and the lower pads disposed in the lower portion of the first semiconductor chip 100. The plurality of connection bumps 150 may include first connection bumps 150a electrically connecting the first wiring layer 510 of the package substrate 500 and the first semiconductor chip 100, and second connection bumps 150b electrically connecting the third wiring layer 530 of the package substrate 500 and the first semiconductor chip 100. The connection bumps 150 may include, for example, an electrically conductive material, such as tin (Sn), indium (In), bismuth (Bi), antimony (Sb), copper (Cu), silver (Ag), zinc (Zn), and lead (Pb), alloys thereof, and/or the like. The alloy may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, and/or the like. In at least some embodiments, the alloy may be a eutectic alloy, such as a solder. Depending on the embodiment, the connection bumps 150 may have a combination of metal pillars and solder balls.

The second semiconductor chip 200 may include a logic chip. The logic chip may include, for example, a central processor (CPU), a graphics processor (GPU), a field programmable gate array (FPGA), a digital signal processor (DSP), a cryptographic processor, a microprocessor, a microcontroller, an analog-to-digital converter, an application-specific semiconductor (ASIC), and/or the like.

The second semiconductor chip 200 according to the present embodiment may be provided in a form of a package (or may be called a ‘second semiconductor package’ or ‘logic chip package (LP)’). For example, the second semiconductor chip 200 may be provided as a first logic chip package LP₁. The first logic chip package LP₁ may include a base substrate 201, a second semiconductor chip 200 disposed on the base substrate 201, and a sealing material 230 surrounding the second semiconductor chip 200 on the base substrate 201. The second semiconductor chip 200 may be disposed on the base substrate 201 through a plurality of connection bump terminals attached to one surface of the second semiconductor chip 200.

The second semiconductor chip 200 may include a substrate 210 and a circuit layer 220.

The substrate 210 may include, for example, an elemental semiconductor such as silicon or germanium (Ge), and/or include a compound semiconductor such as silicon carbide (SiC), gallium arsenide (GaAs), indium arsenide (InAs), or indium phosphide (InP).

A circuit layer 220 may be disposed on an active surface of the substrate 210. The circuit layer 220 may include an interlayer insulating layer and a wiring structure. The interlayer insulating layer may include an electrically insulating material, such as FOX (Flowable Oxide), TOSZ (Tonen SilaZen), USG (Undoped Silica Glass), BSG (Borosilica Glass), PSG (PhosphoSilaca Glass), BPSG (BoroPhosphoSilica Glass), PETEOS (Plasma Enhanced Tetra Ethyl Ortho Silicate), FSG (Fluoride Silicate Glass), HDP (High Density Plasma) oxide, PEOX (Plasma Enhanced Oxide), FCVD (Flowable CVD) oxide, a combination thereof, and/or the like. The interlayer insulating layer may be formed using chemical vapor deposition (CVD), a flowable-CVD process, or a spin coating process. The wiring structure may be disposed between the substrate 210 and the plurality of connection bump terminals, and embedded in the interlayer insulating layer. The wiring structure may be formed as a multilayer structure including wiring patterns and vias formed of an electrically conductive material, for example, aluminum (Al), gold (Au), cobalt (Co), copper (Cu), nickel (Ni), lead (Pb), tantalum (Ta), tellurium (Te), titanium (Ti), tungsten (W), a combination thereof, and/or the like. The first logic chip package LP₁ may be disposed on the second region R2 of the package substrate 500. An interposer substrate 300 may be disposed between the first logic chip package LP₁ and the second region R2 of the package substrate 500. The first logic chip package LP₁ and the package substrate 500 may be electrically connected to each other via the interposer substrate 300.

The interposer substrate 300 may be disposed between an upper surface of the second region R2 of the package substrate 500 and the second semiconductor chip 200, to correct a difference in coefficients of thermal expansion (CTE) between the package substrate 500 and the second semiconductor chip 200, and to prevent and/or alleviate a warpage phenomenon or the semiconductor package 1000. In addition, passive devices 10 may be mounted on the interposer substrate 300, and the mounting quality of the passive devices 10 can be further improved as the warpage phenomenon of the semiconductor package 1000 is prevented or alleviated.

The interposer substrate 300 may also include a substrate 301, lower pads 302, upper pads 303, and a plurality of connection wirings.

The substrate 301 may be formed of, for example, at least one of a silicon substrate, an organic substrate, a plastic substrate, a glass substrate, and/or the like. When the substrate 301 is a silicon substrate, the interposer substrate 300 may be referred to as a silicon interposer. Unlike what is illustrated in the drawing, when the substrate 301 is an organic substrate, the interposer substrate 300 may be referred to as a panel interposer.

The lower pads 302 may be disposed in a lower portion of the interposer substrate 300 so that a lower surface thereof is exposed. The upper pads 303 may be disposed in an upper portion of the interposer substrate 300 so that an upper surface thereof is exposed. The lower pads 302 and upper pads 303 of the interposer substrate 300 may include a material similar to the front pad and lower pad of the package substrate 500, but the example embodiments thereof are not limited thereto.

At least a portion of the plurality of wirings may electrically connect the lower pads 302 and the upper pads 303. The plurality of wirings may include a first wiring 310 electrically connecting the second semiconductor chip 200 and the second wiring layer 520 of the package substrate 500, and a second wiring 320 electrically connecting the second semiconductor chip 200 and the fourth wiring layer 540 of the package substrate 500.

The interposer substrate 300 may be disposed to be spaced apart from a side surface ds of the step d formed at a boundary between the first region R1 and the second region R2. For example, the side surface 300S of the interposer substrate may be spaced apart from the side surface ds of the step d, so that a predetermined (or otherwise determined) space SP may be formed between the side surface 300S of the interposer substrate and the side surface ds of the step d.

Passive devices 10 including a capacitor 10a, a resistor 10b, and/or the like may be disposed on one surface of the interposer substrate 300. According to the present embodiment, I/O of the second semiconductor chip 200 may be increased/and/or maximized by disposing the passive devices 10 in parallel with the second semiconductor chip 200 on the interposer substrate 300. The interposer substrate 300 may further include a third connection wiring connecting the passive devices 10 and at least a portion of the lower pads 302.

A plurality of bump structures 350 may be disposed between the interposer substrate 300 and the second region R2 of the package substrate 500.

The bump structures 350 may electrically connect front pads disposed in the second region R2 of the package substrate 500 and lower pads disposed below the interposer substrate 300. The plurality of bump structures 350 may include first bump structures 350a electrically connecting the interposer substrate 300 and the second wiring layer 520 of the package substrate 500, and second bump structures 350b electrically connecting the interposer substrate 300 and the fourth wiring layer 540 of the package substrate 500.

The bump structures 350 disposed on the second region R2 may be located on a level lower than that of the connection bumps 150 disposed on the first region R1.

An upper surface of the interposer substrate 300 disposed on the bump structures 350 may be spaced apart from an upper surface of the second region R2 of the package substrate 500 by a first distance (t). The first distance (t) may have the same and/or a substantially similar range as the step (d). That is, the first distance (t) may range from about 50 um or less, for example, from 10 um to 40 um, or from 10 um to 35 um.

The bump structures 350 may include a material similar to the connection bumps 150 disposed between the first semiconductor chip 100 and the first region R1 of the package substrate 500. However, the materials of the bump structures 350 and the connection bumps 150 are not limited to the above-described materials.

A plurality of connection terminals 250 may be disposed between the second semiconductor chip 200 and the interposer substrate 300.

The connection terminals 250 may electrically connect metal pads disposed in a lower portion of the second base substrate 202 of the first logic chip package LP; and upper pads 303 disposed in an upper portion of the interposer substrate 300. The connection terminals 250 may include first connection terminals 250a electrically connecting the second semiconductor chip 200 disposed on the second base substrate 202 and the first connection wiring 310, and second connection terminals 250b electrically connecting the second semiconductor chip 200 and the second connection wiring 310 of the interposer substrate 300. The second semiconductor chip 200 may be electrically connected to the second wiring layer 520 through the first connection wiring 310 electrically connecting the first connection terminal 250a and the first bump structure 350a. In addition, the second semiconductor chip 200 may be electrically connected to the fourth wiring layer 540 through the second connection wiring 320 electrically connecting the second connection terminal 250b and the second bump structure 350b.

In at least one embodiment, the connection terminals 250 disposed on the second region R2 may be located at the same and/or substantially similar level as the connection bumps 150 disposed on the first region R1.

The connection terminals 250 may include a material similar to the connection bumps 150 disposed between the first semiconductor chip 100 and the first region R1 of the package substrate 500. However, the materials of the connection terminals 250 and connection bumps 150 are not limited to the above-described materials.

The interposer substrate 300 and the second semiconductor chip 200 may be fixed on an upper surface of the second region R2 of the package substrate 500 by an underfill 400 (or ‘underfill layer’). The underfill 400 surrounds the bump structures 350, the interposer substrate 300, and the connection terminals 250 on the upper surface of the second region R2 of the package substrate 500, and contact at least a portion of the first logic chip package LP and/or LP₁ including the second semiconductor chip 200. The underfill 400 may surround passive devices 10 disposed on the interposer substrate 300. The underfill 400 may form protrusions 400S on side and upper portions of the passive devices 10. The underfill 400 may include an insulating material. The underfill 400 may be formed using a capillary underfill (CUF) process, but the example embodiments thereof are not limited thereto.

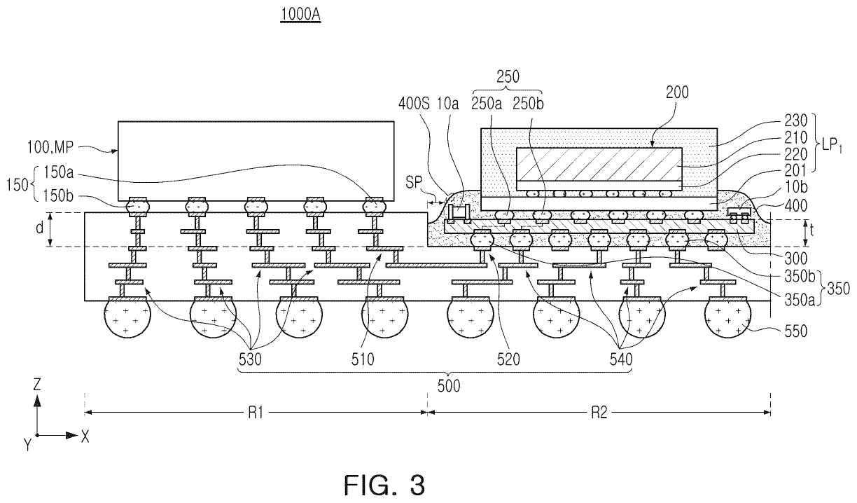

FIG. 3 is a cross-sectional view illustrating a semiconductor package 1000A according to at least one example embodiment of the present inventive concepts.

Referring to FIG. 3, the semiconductor package 1000A of at least one example embodiment may have the same or similar characteristics as those described with reference to FIGS. 1 and 2, except that a first distance di in which the interposer substrate 300 is spaced apart from an upper surface of the second region R2 of the package substrate 500 is smaller than the step d between the upper surfaces of the first region R1 and the second region R2.

In at least one example embodiment, the first distance ti may range from about 45 um or less, for example, from 5 um to 35 um, and/or from 5 um to 30 um. For example, a difference between the step (d) and the first distance ti may be about 2 um or more, for example, 2 um to 5 um, or 3 um to 5 um.

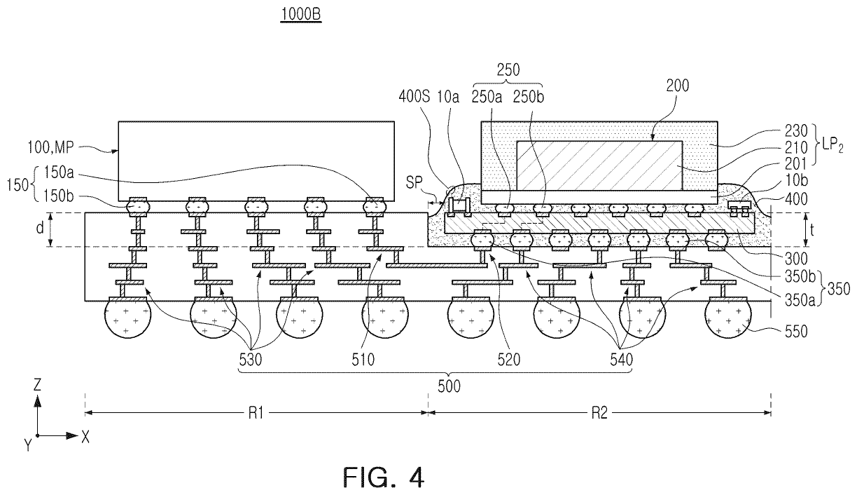

FIG. 4 is a cross-sectional view illustrating a semiconductor package 1000B according to at least one example embodiment of the present inventive concepts.

Referring to FIG. 4, the semiconductor package 1000B of at least one example embodiment may have the same or similar characteristics as those described with reference to FIGS. 1 and 2, except that the second semiconductor chip 200 may be provided as a second logic chip package LP₂.

The second logic chip package LP₂ may include a base substrate 201, a second semiconductor chip 200 disposed on an upper surface of the base substrate 201, and a sealing material 230 surrounding the second semiconductor chip 200 on the base substrate 201. In at least some embodiments of the second logic chip package LP₂, the second semiconductor chip 200 may be formed from the base substrate 201 and/or the second semiconductor chip 200 may be bonded to the base substrate 201 using, e.g., a hybrid bonding (e.g., a Cu—Cu direct hybrid bond) such that the connection bumps are omitted from between the second semiconductor chip 200 and the base substrate 201.

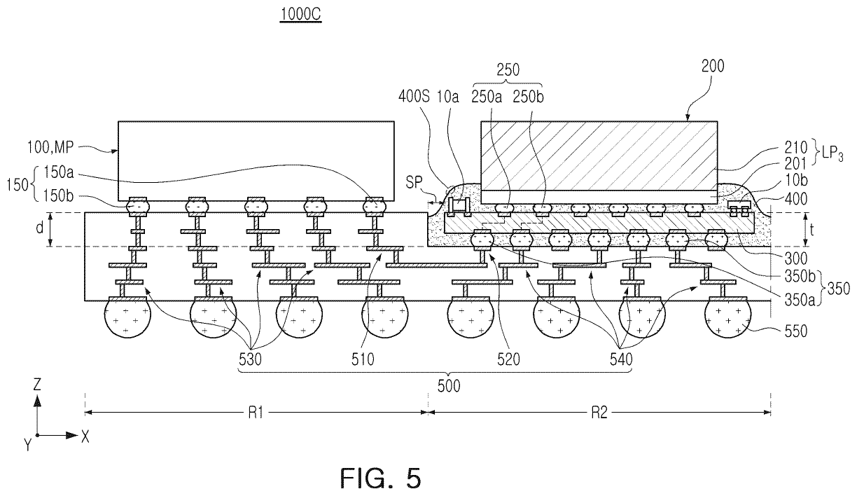

FIG. 5 is a cross-sectional view illustrating a semiconductor package 1000C according to at least one example embodiment of the present inventive concepts.

Referring to FIG. 5, the semiconductor package 1000C of at least one example embodiment may have the same or similar characteristics as those described with reference to FIGS. 1 and 2, except that the second semiconductor chip 200 may be provided as a third logic chip package LP₃.

The third logic chip package LP; may include a base substrate 201 and a second semiconductor chip 200 disposed on the base substrate 201. In at least some embodiments of the third logic chip package LP₃, the second semiconductor chip 200 may be formed from the base substrate 201 and/or the second semiconductor chip 200 may be bonded to the base substrate 201 using, e.g., a direct metal bond (e.g., Cu—Cu) such that the connection bumps are omitted from between the second semiconductor chip 200 and the base substrate 201.

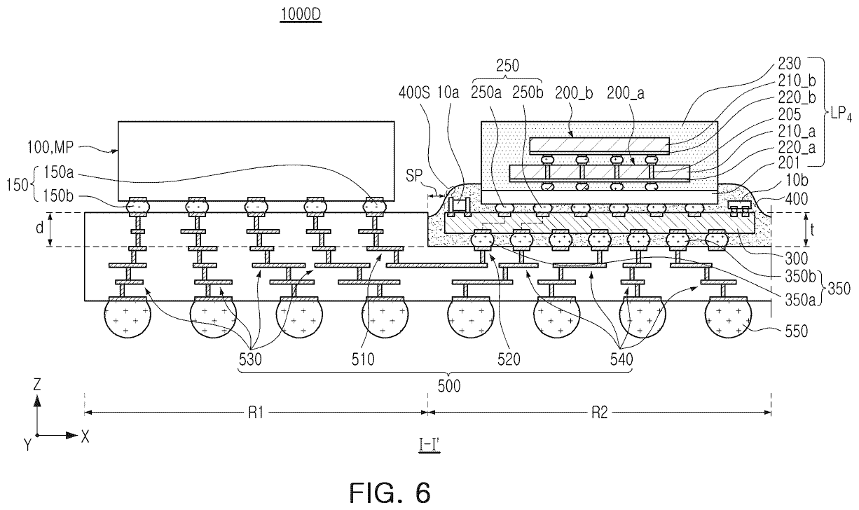

FIG. 6 is a cross-sectional view illustrating a semiconductor package 1000D according to at least one example embodiment of the present inventive concepts.

Referring to FIG. 6, the semiconductor package 1000D of at least one example embodiment may have the same or similar characteristics as those described with reference to FIGS. 1 and 2, except that the semiconductor package 100D may be provided as a fourth logic chip package LP₄ in which a base substrate 201 is stacked on an interposer substrate 300, and a plurality of semiconductor dies 200_a and 200_b (or ‘a plurality of semiconductor chips (200_a, 200_b)’) are stacked on the base substrate 201.

The fourth logic chip package LP₄ may include a base substrate 201, a plurality of semiconductor dies 200_a, 200_b, vertically stacked on the base substrate 201, and a sealing material 210 covering the plurality of semiconductor dies 200_a, 200_b on the base substrate 201. For example, the fourth logic chip package LP₄ may include a first semiconductor die 200_a (or ‘first semiconductor chip 200_a’) and a second semiconductor die 200_b stacked on the first semiconductor die 200_a (or ‘second semiconductor die 200_b’), but the number of stacked semiconductor dies is not limited thereto.

The first semiconductor die 200_a may include a first substrate 210_a, a first circuit layer 220_a, through-electrodes 205, and first connection pads. The first connection pads may include first front connection pads disposed on a front surface of the first semiconductor die 200_a, and first rear connection pads disposed on a rear surface of the first semiconductor die 200_a. The first substrate 210_a, the first circuit layer 220_a, and the first connection pads may have the same or similar characteristics as the substrate 210, the circuit layer 220, and the front and rear pads described above with reference to FIG. 2.

Through-electrodes 205 may penetrate through the first substrate 210_a, and electrically connect at least a portion of the first front connection pads and at least a portion of the first rear connection pads disposed on a front surface thereof. The through-electrodes 205 may include a via plug (not shown) and a side barrier film (not shown) surrounding a side surface of the via plug. The via plug may include a conductive material, for example, tungsten (W), titanium (Ti), aluminum (Al), copper (Cu), and/or the like, and may be formed through a plating process, a physical vapor deposition (PVD) process, a chemical vapor deposition (CVD) process, and/or the like. The side barrier film may include a conductive material, for example, titanium (Ti), titanium nitride (TiN), tantalum (Ta), tantalum nitride (TaN), and/or the like, and may be formed through a plating process, a PVD process, a CVD process, and/or the like.

The first semiconductor die 200_a may be attached to the base substrate 201 by a plurality of first connection bump structures disposed on a lower surface of the first semiconductor die 200_a.

The second semiconductor die 200_b may include a second substrate 210_b, a second circuit layer 220_b, and second connection pads. The second connection pads may be disposed on a front surface of the second semiconductor die 200_b. The second substrate 210_b, the second circuit layer 220_b, and the second connection pads may have the same or similar characteristics as the substrate 210, the circuit layer 220, and the front and rear pads described above with reference to FIG. 2.

The first semiconductor die 200_a and the second semiconductor die 200_b may be electrically connected, e.g., by second connection bump structures disposed between the first rear connection pads of the first semiconductor die 200_a and the second connection pads of the second semiconductor die 200_b, but the example embodiments thereof are not limited thereto. For example, when the first rear connection pads of the first semiconductor die 200_a and the second connection pads of the second semiconductor die 200_b are copper (Cu), the first semiconductor die 200_a and the second semiconductor die 200_b may be electrically connected by hybrid bonding between the first rear connection pads and the second connection pads.

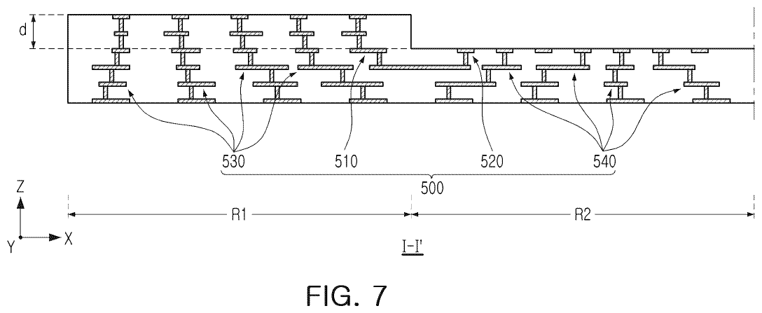

FIGS. 7 to 13 are cross-sectional views schematically illustrating a manufacturing process of a semiconductor package 1000 according to at least one example embodiment of the present inventive concepts.

Referring to FIG. 7, a package substrate 500 having an upper surface having a step d in a first region R1 and a second region R2 may be provided. After a body copper clad laminate and/or a copper clad laminate having a constant thickness is formed over the first region R1 and the second region R2, the package substrate 500 may be formed by disposing a mask on the second region R2 and additionally stacking a wiring layer only on the first region R1. In this case, the number of wiring layers located in the first region R1 may be greater than the number of wiring layers located in the second region R2, and the uppermost wiring layer located in the first region R1 may be disposed on a level higher than that of the uppermost wiring layer of the wiring layer located in the second region R2.

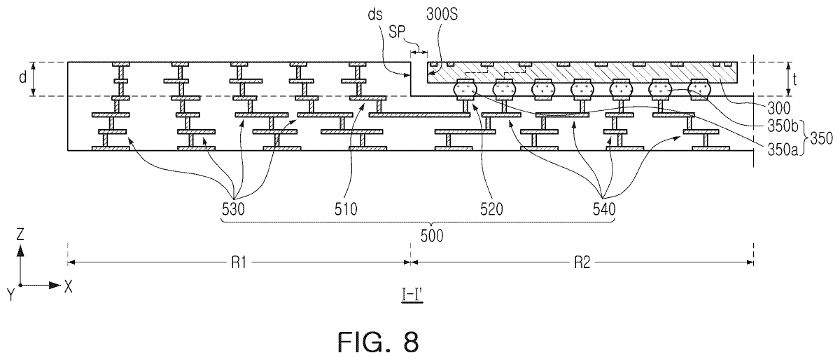

Referring to FIG. 8, the interposer substrate 300 may be mounted on an upper surface of the second region R2 of the package substrate 500 using a bump structure 350. A side surface 300S of the interposer substrate may be mounted an upper surface of the second region R2 so as to be spaced apart from a side surface ds of a step formed at a boundary between the first region R1 and the second region R2. A space SP may be formed between the side surface 300S of the interposer substrate and the side surface ds of the step.

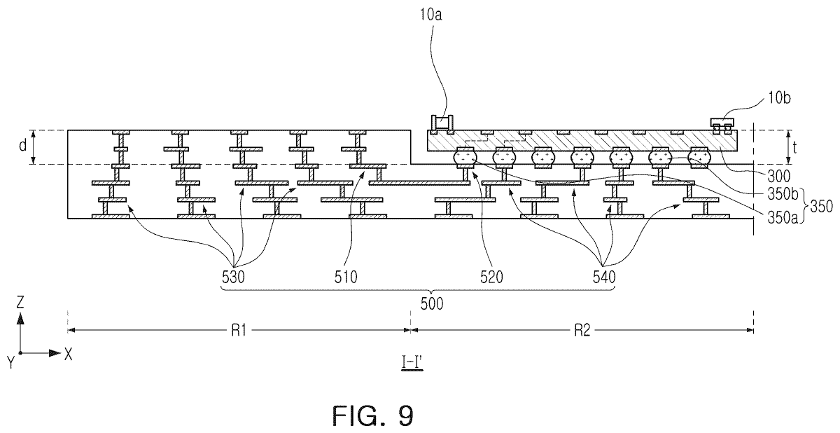

Referring to FIG. 9, passive devices 10 including at least one capacitor 10a and at least one resistor 10b may be mounted on the interposer substrate 300. The passive devices 10 may be mounted on at least a portion of the upper pads 303 disposed above the interposer substrate 300 using a surface mount technology (SMT) method using a connection member (such as solder, but the example embodiments thereof are not limited thereto).

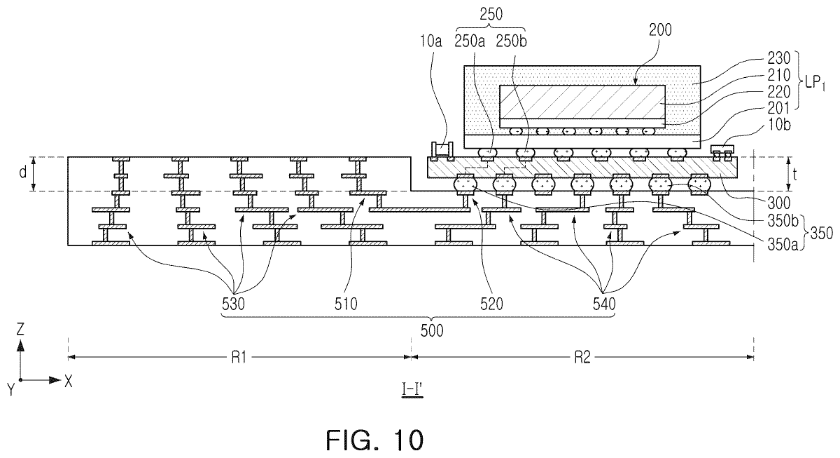

Referring to FIG. 10, the first logic chip package LP₁ (or the second logic chip package LP₂, the third logic chip package LP₃, or the fourth logic chip package LP₄) in which the second semiconductor chip 200 (or semiconductor dies 200_a, 200_b) is embedded may be mounted on the interposer substrate 300 using connection terminals 250. The first logic chip package LP₁ may be mounted on the interposer substrate 300 in parallel with the passive devices 10.

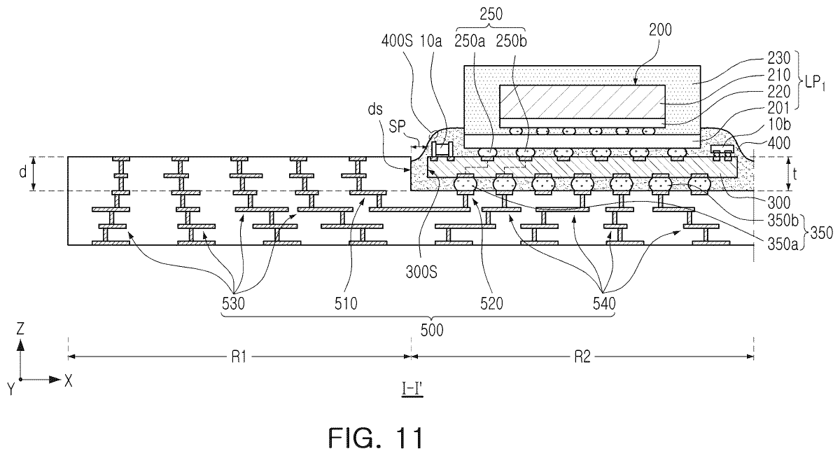

Referring to FIG. 11, an underfill 400 may be filled in a second region R2 of a package substrate 500 to fix the interposer substrate 300 and the second semiconductor chip 200 to) an upper surface of the second region R2 of the package substrate 500. The underfill 400 may be formed to surround the passive devices 10 and the connection terminals 250 on the upper surface of the interposer substrate 300. Thereafter, the underfill 400 may flow downwardly to contact the upper surface of the second region R2 of the package substrate 500 through the space SP between the side surface 300S of the interposer substrate and the side surface ds of the step. Finally, the underfill 400 may surround the bump structures 350, and fill a region between the upper surface of the second region R2 of the package substrate 500 and the interposer substrate 300. The underfill 400 may contact at least a portion of a lower portion of the first logic chip package LP₁, and may form the protrusion 400S in a side portion of the passive device 10. The underfill 400 may be formed by a Capillary Underfill (CUF) process, but the example embodiments thereof are not limited thereto.

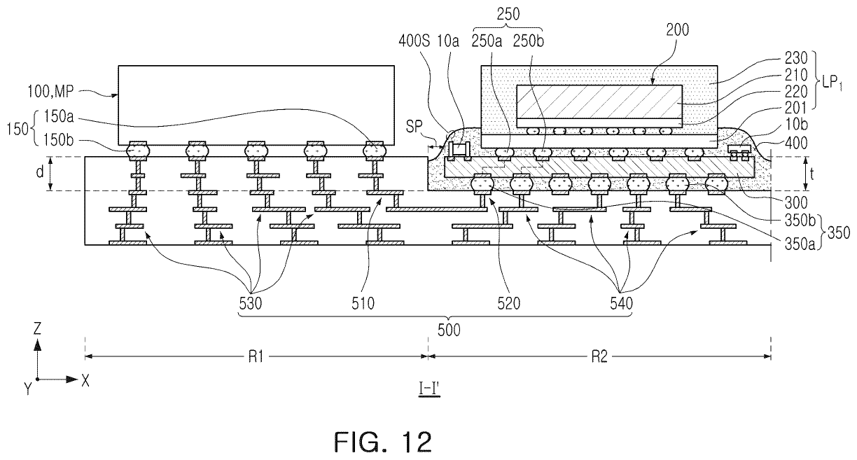

Referring to FIG. 12, a first semiconductor chip 100 or a package MP including the first semiconductor chip 100 may be mounted on the upper surface of the first region R1 of the package substrate 500 by the connection bumps 150 thereby forming a structure hereinafter, referred to as ‘preliminary package assembly’.

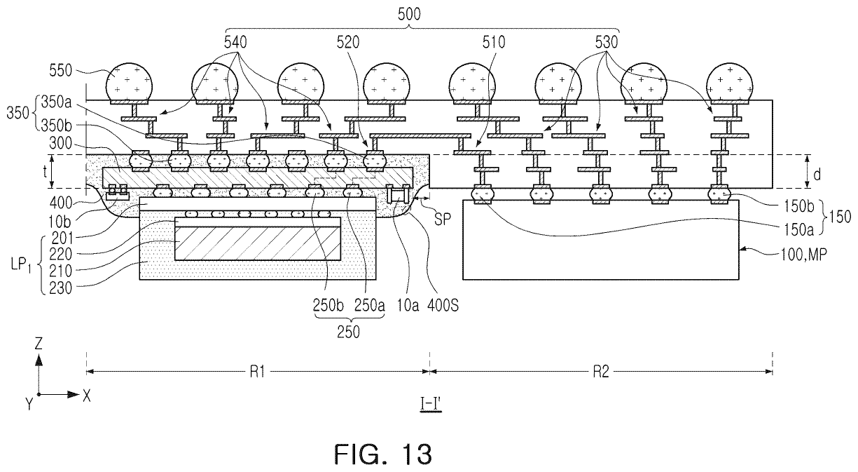

Referring to FIG. 13, the preliminary package assembly according to FIG. 12 may be provided to be face-up. As illustrated in FIG. 13, external connection terminals 750 may be attached to rear pads disposed on a lower surface of the package substrate 500.

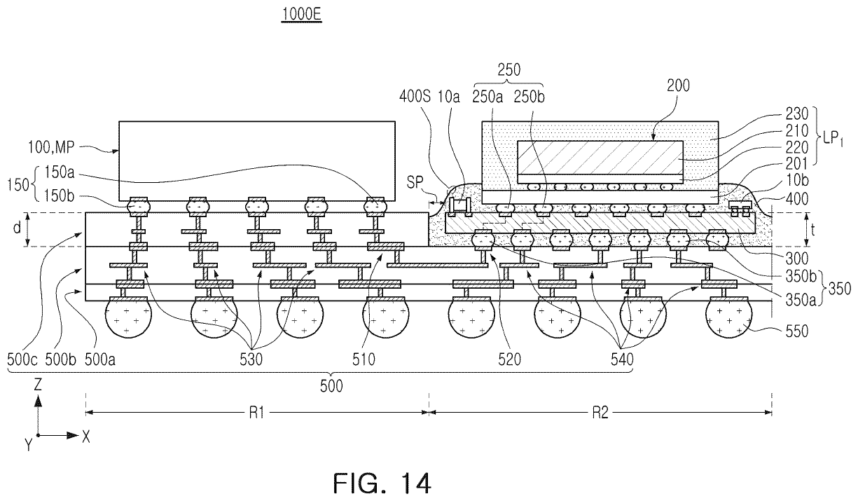

FIG. 14 is a cross-sectional view illustrating a semiconductor package 1000E according to at least one example embodiment of the present inventive concepts.

Referring to FIG. 14, the semiconductor package 1000E of at least one example embodiment may include a package substrate 500 comprised of a plurality of layers, at least one first semiconductor chip 100, a second semiconductor chip 200, and an interposer substrate 300. At least one of the first semiconductor chip 100, the second semiconductor chip 200, and the interposer substrate 300 may have the same or similar characteristics as the semiconductor package 1000 described with reference to FIGS. 1 and 2. The semiconductor package 1000E may have a package substrate 500 comprised of a plurality of substrates and a plurality of layers. For example, the package substrate 500 may be comprised of a first layer 500a, a second layer 500b, and a third layer 500c. Specifically, the package substrate 500 may include a first layer 500a and a second layer 500b disposed on the first layer 500a, over a first region R1 and a second region R2, in a horizontal direction. Here, the third layer 500c may be limitedly disposed on an upper surface of a portion of the second layer 500b located in the first region R1. In this case, a difference in levels of an upper surface of the first region R1 and an upper surface of the second region R2 may be equal to a thickness of the third layer 500c.

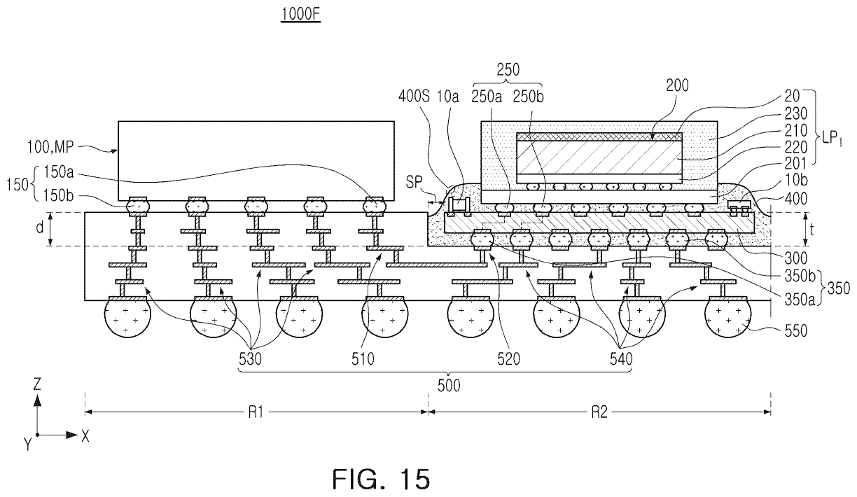

FIG. 15 is a cross-sectional view showing a semiconductor package 1000F according to at least one example embodiment of the present inventive concepts.

Referring to FIG. 15, the semiconductor package 1000F of at least one example embodiment may have the same or similar features as those described with reference to FIGS. 1 and 2, except that the semiconductor package 1000F further includes a heat dissipation structure 20 in which a first logic chip LP₁ is disposed on the second semiconductor chip 200. For reference, the semiconductor packages 1000A, 1000B, 1000C, 1000D, and 1000E described with reference to FIGS. 3, 4, 5, 6, and 14 may also include the heat dissipation structure 20.

For example, the semiconductor package 1000E may include a heat dissipation structure 20 having high thermal conductivity. The heat dissipation structure 20 may be disposed on a second semiconductor chip 200. The heat dissipation structure 20 may effectively discharge heat generated from the second semiconductor chip 200 in a direction of an upper surface thereof and/or in a direction of an upper surface of a ‘sealing material 210’).

The heat dissipation structure 20 may be formed of a material having higher thermal conductivity than the sealing material 210. For example, the heat dissipation structure 20 may include copper (Cu), but the example embodiments thereof are not limited thereto. For example, the heat dissipation structure 300 may include metal such as nickel (Ni), gold (Au), silver (Ag), aluminum (Al), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), and ruthenium (Ru), an alloy thereof, and/or the like.

As set forth above, according to example embodiments of the present inventive concepts, by providing a substrate having a step, it is possible to provide a semiconductor package, which is advantageous in miniaturization and has improved performance.

The various and advantageous advantages and effects of the present inventive concepts are not limited to the above description, and may be more easily understood in the course of describing the specific embodiments of the present inventive concepts. While example embodiments have been shown and described above, it will be apparent to those skilled in the art that modifications and variations could be made without departing from the scope of the present inventive concepts, as defined by the appended claims.

While example embodiments have been shown and described above, it will be apparent to those skilled in the art that modifications and variations could be made without departing from the scope of the present inventive concepts as defined by the appended claims.

What is claimed is:

1. A semiconductor package, comprising:
a package substrate including a plurality of wiring layers and having a first region and a second region, such that an upper surface of the second region is disposed at a level lower than that of an upper surface of the first region;
a first semiconductor chip on the upper surface of the first region and electrically connected to the plurality of wiring layers of the package substrate;
a second semiconductor chip on the upper surface of the second region; and
an interposer substrate between the upper surface of the second region and the second semiconductor chip, and the interposer substrate electrically connecting the plurality of wiring layers of the package substrate and the second semiconductor chip.

2. The semiconductor package of claim 1, wherein the plurality of wiring layers comprise
at least one first wiring layer in the first region, the at least one first wiring layer electrically connected to the first semiconductor chip, and
at least one second wiring layer in the second region, the at least one second wiring layer electrically connected to the interposer substrate, and
the at least one first wiring layer and the at least one second wiring layer are electrically connected to each other in the package substrate at a boundary between the first region and the second region.

3. The semiconductor package of claim 2, wherein a number of layers of the at least one first wiring layer is greater than a number of layers of the at least one second wiring layer.

4. The semiconductor package of claim 1, further comprising:
a passive device on the interposer substrate in parallel with the second semiconductor chip, and the passive device electrically connected to the second semiconductor chip through the interposer substrate.

5. The semiconductor package of claim 2, further comprising:
a plurality of connection bumps between the first semiconductor chip and the first wiring layer, and the plurality of connection bumps electrically connecting the first semiconductor chip and the first wiring layer.

6. The semiconductor package of claim 5, further comprising:
a plurality of bump structures between the interposer substrate and the second wiring layer, and the plurality of bump structures electrically connecting the interposer substrate and the second wiring layer.

7. The semiconductor package of claim 6, wherein the plurality of connection bumps between the first semiconductor chip and the first wiring layer are at a level higher than that of the plurality of bump structures between the interposer substrate and the second wiring layer.

8. The semiconductor package of claim 6, further comprising:
a plurality of connection terminals between the second semiconductor chip and the interposer substrate, and the plurality of connection terminals electrically connecting the second semiconductor chip and the interposer substrate.

9. The semiconductor package of claim 8, further comprising:
an underfill layer surrounding the plurality of bump structures, the interposer substrate, and the plurality of connection terminals on the upper surface of the second region.

10. The semiconductor package of claim 1, wherein a difference in levels between the upper surface of the first region and the upper surface of the second region is within a range of about 10 micrometers (um) to 35 um.

11. The semiconductor package of claim 10, wherein the level of the upper surface of the first region is at a same level as that of an upper surface of the interposer substrate.

12. The semiconductor package of claim 10, wherein the level of the upper surface of the first region is at a level higher than that of an upper surface of the interposer substrate.

13. The semiconductor package of claim 12, wherein a difference between the level of the upper surface of the first region and a level of an upper surface of the interposer substrate is within a range of about 2 micrometers (um) to 5 um.

14. A semiconductor package, comprising:
a package substrate divided into a first region and a second region in a horizontal direction, and including a first wiring structure in the first region and a second wiring structure in the second region, the second wiring structure connected to the first wiring structure;
a first semiconductor chip on the first region of the package substrate and electrically connected to the first wiring structure;
an interposer substrate on the second region of the package substrate and electrically connected to the second wiring structure; and
a second semiconductor chip on the interposer substrate and electrically connected to the interposer substrate,
wherein a number of layers of the second wiring structure is less than a number of layers of the first wiring structure, and an uppermost wiring layer of the first wiring structure is on a level higher than an uppermost wiring layer of the second wiring structure.

15. The semiconductor package of claim 14, wherein the package substrate further comprises
a third wiring structure in the first region; and
a fourth wiring structure in the second region, and
the fourth wiring structure has a smaller number of layers than the third wiring structure.

16. The semiconductor package of claim 15, further comprising:
first connection bumps electrically connecting the first semiconductor chip and the first wiring layer;
second connection bumps electrically connecting the first semiconductor chip and the third wiring layer;
first bump structures electrically connecting the second semiconductor chip and the second wiring layer; and
second bump structures electrically connecting the second semiconductor chip and the fourth wiring layer.

17. The semiconductor package of claim 16, wherein
the first semiconductor chip comprises a memory chip, and the second semiconductor chip comprises a logic chip, and
the semiconductor package, further comprising a passive device on the interposer substrate in parallel with the logic chip, the passive device electrically connected to the logic chip through the interposer substrate.

18. A semiconductor package, comprising:
a package substrate having a first region and a second region, such that an upper surface of the second region is disposed at a level lower than that of an upper surface of the first region;
a first semiconductor package on the upper surface of the first region of the package substrate;
a plurality of connection bumps between the upper surface of the first region of the package substrate and the first semiconductor package, and connecting the package substrate and the first semiconductor package;
an interposer substrate on the upper surface of the second region of the package substrate;
a plurality of bump structures between the upper surface of the second region of the package substrate and the interposer substrate, and connecting the package substrate and the interposer substrate;
a second semiconductor package on the interposer substrate;
a plurality of connection terminals between the interposer substrate and the second semiconductor package, and the plurality of connection terminals connecting the interposer substrate and the second semiconductor package; and
a plurality of external connection terminals disposed on a lower surface of the package substrate.

19. The semiconductor package of claim 18, wherein the second semiconductor package comprises
a base substrate,
a first semiconductor die on the base substrate, the first semiconductor die including at least one through-electrode; and
a second semiconductor die on the first semiconductor die and electrically connected to the at least one through-electrode.

20. The semiconductor package of claim 18, further comprising:
a heat dissipation member on the second semiconductor package.
